(19) United States
(12) Patent Application Publication
(10) Pub. No.: US 2021/0076513 A1
(43) Pub. Date: Mar. 11, 2021

(54) ELECTRONIC CONTROLLER

(71) Applicant: HITACHI AUTOMOTIVE SYSTEMS, LTD., Hitachinaka-shi, Ibaraki (JP)

(72) Inventors: Takayuki FUKUZAWA, Ibaraki (JP); Yoshio KAWAI, Ibaraki (JP); Yujiro KANEKO, Ibaraki (JP)

(73) Assignee: HITACHI AUTOMOTIVE SYSTEMS, LTD., Hitachinaka-shi, Ibaraki (JP)

(21) Appl. No.: 16/959,532

(22) PCT Filed: Jan. 8, 2019
(86) PCT No.: PCT/JP2019/000143

§ 371 Date: Jul. 1, 2020

(30) Foreign Application Priority Data
Jan. 25, 2018 (JP) 2018-010467

(51) Int. Cl. H05K 5/00; H05K 7/20

(52) U.S. Cl. CPC H05K 5/0026; H05K 7/2039

(57) ABSTRACT

To provide an electronic controller by which a heat dissipation property for an electronic part can be enhanced. The electronic controller is an electronic controller including a circuit board on which an electronic part is mounted, and a housing accommodating the circuit board. A metallic plate facing the electronic part is provided at part of the housing, and an outer surface of the metallic plate is covered with a second resin film thinner than the metallic plate. An inner surface of the metallic plate is covered with a first resin film thinner than the metallic plate.

### TECHNICAL FIELD

The present invention relates to an electronic controller mounted on a vehicle.

### BACKGROUND ART

An electronic controller such as an engine control unit or an automatic transmission control unit is mounted on a vehicle, specifically, in a compartment or an engine room. The electronic controller includes, for example, a circuit board, a connector mounted on the circuit board, a housing accommodating the circuit board, a seal member for securing airtightness of the inside of the housing, and the like.

Patent Document 1 discloses an electronic controller that includes a housing having a case and a cover joined to each other, a circuit board accommodated in the inside space of the housing, a connector mounted to the circuit board, and the like. The case and the cover in Patent Document 1 are joined to each other by a seal member.

### PRIOR ART DOCUMENT

### Patent Document

Patent Document 1: Japanese Patent Laid-open No. 2014-187063

### SUMMARY OF INVENTION

### Technical Problem

Incidentally, the electronic controller is required to be reduced in weight attendantly on the recent years' severer requirements concerning fuel economy improvement and exhaust emission regulation, and to cope with heat dissipation from electronic parts.

The present invention has been made in consideration of the above-mentioned circumstances. It is an object of the present invention to provide an electronic controller by which a heat dissipation property for an electronic part can be enhanced.

### Technical Solution

An electronic controller according to one aspect for solving the above-mentioned problem is an electronic controller including a circuit board on which an electronic part is mounted, and a housing accommodating the circuit board. A metallic plate facing the electronic part is provided at part of the housing. At least an outer surface of the metallic plate is covered with a resin film thinner than the metallic plate.

### Advantageous Effect

According to the present invention, a heat dissipation property for an electronic part is enhanced through a metallic plate.

### BRIEF DESCRIPTION OF DRAWINGS

FIG. 1 is a sectional view of an electronic controller according to Embodiment 1.

FIG. 2 is an enlarged sectional view of the electronic controller according to Embodiment 1.

FIG. 3 is a diagram schematically representing the relation between a heat dissipation performance lowering allowance ΔTa(d) based on heat conduction of a second resin film and a heat dissipation performance enhancement allowance ΔTb(d) based on thermal radiation according to Embodiment 1.

FIG. 4 is a sectional view of an electronic controller according to Embodiment 2.

FIG. 5 is a sectional view of an electronic controller according to Embodiment 3.

FIG. 6 is a perspective view of an electronic controller according to Embodiment 4.

FIG. 7 is a sectional view of the electronic controller according to Embodiment 4.

FIG. 8 is a sectional view of an electronic controller according to Embodiment 5.

FIG. 9 is an exploded perspective view of an electronic controller according to Embodiment 6.

FIG. 10 is a sectional view of the electronic controller according to Embodiment 6.

FIG. 11 is a sectional view of an electronic controller according to Embodiment 7.

### MODES FOR CARRYING OUT THE INVENTION

Some embodiments will be described in detail, referring to the drawings. Note that the embodiments described below do not limit the invention according to the claims, and all the elements and combinations thereof described in the embodiments are not necessarily indispensable to the solving means of the invention.

### Embodiment 1

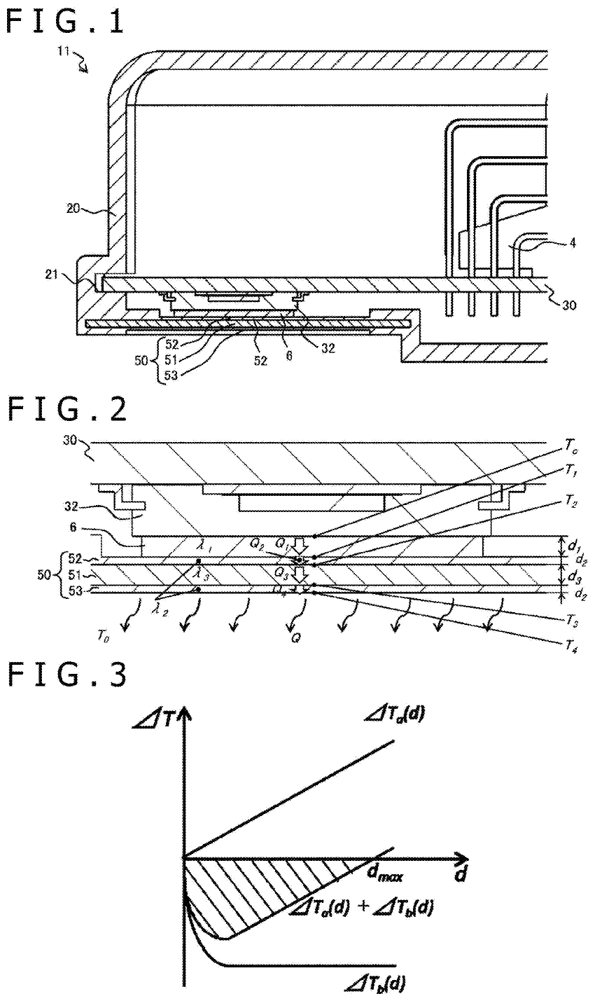

FIG. 1 is a sectional view of an electronic controller according to Embodiment 1.

The electronic controller 11 includes a housing 20 and a circuit board 30. The housing 20 is formed in a bottomed tubular shape having an opening, and accommodates the circuit board 30. Specifically, a peripheral edge of the housing 20 exclusive of the opening is formed with a stepped part 21, and the circuit board 30 is supported by the stepped part 21. The material of the housing 20 may be preferably a resin material selected from among PBT, PPS and the like.

The circuit board 30 has an electronic part 32 mounted on a printed wiring board based on, for example, a glass-epoxy resin or the like. Examples of the electronic part 32 include a microprocessor, a memory, other integrated circuits, a capacitor, and a resistor. The electronic part or parts 32 may be mounted on one surface or both surfaces of the circuit board 30.

The electronic part 32 is mounted at a position spaced inward by a predetermined distance from a portion of being supported by the stepped part 21, of the circuit board 30. A plurality of connectors 4 (in FIG. 1, only one connector 4 is depicted, and the other connectors are omitted) electrically connected to an external connector are mounted on one end side of the circuit board 30.

A resin-coated metallic plate 50 facing the electronic part 3 is provided at part of the housing 20. The resin-coated metallic plate 50 may be insert molded in relation to the housing 20.

The resin-coated metallic plate 50 includes a metallic plate 51, and a first resin film 52 and a second resin film 53 which are thinner than the metallic plate 51. The first resin film 52 covers an inner surface of the metallic plate 51. The second resin film 53 covers an outer surface of the metallic plate 51. The resin-coated metallic plate 50 may preferably include at least the second resin film 53, of the first resin film 52 and the second resin film 53.

The metallic plate 51, the first resin film 52, and the second resin film 53 are fixed in close contact with one another by an adhesive in a thin form. The material of the metallic plate 51 may preferably be a metallic material selected from among aluminum, iron and the like. The material of the first resin film 52 and the second resin film 53 may preferably be a resin material selected from among PBT, PPS and the like.

Note that the housing 20, the first resin film 52, and the second resin film 53 may be formed from the same resin material. With these members formed from the same material, for example, good adhesion of the housing 20 can be expected at the time of insert molding of the resin-coated metallic plate 50.

A heat conductive material 6 is provided between the electronic part 3 and the first resin film 52. The heat conductive material 6 is placed to fill the space between the electronic part 3 and the first resin film 52. Heat generated from the electronic part 3 is transmitted through the heat conductive material 6 to the first resin film 52, the metallic plate 51, and the second resin film 53 in this order. Part of the heat transmitted to the first resin film 52, the metallic plate 51, and the second resin film 53 is transmitted to the housing 20. The heat transmitted to the second resin film 53 is dissipated to the external environment.

FIG. 2 is an enlarged sectional view of the electronic controller according to Embodiment 1.

Next, heat dissipation from the electronic part 32 through the heat conductive material 6, the first resin film 52, the metallic plate 51, and the second resin film 53 will be described in detail. Heat transport quantities Q1, Q2, Q3, and Q4 through the heat conductive material 6, the first resin film 52, the metallic plate 51, and the second resin film 53 in thickness direction are represented by the following mathematical formula 1, mathematical formula 2, mathematical formula 3, and mathematical formula 4, respectively.

$$\begin{matrix}Q 1 = A 1 ( Tc - T 1 ) \frac{λ 1}{d 1} & [ Mathematical 1 ] \\ Q 2 = A 2 ( T 1 - T2 ) \frac{λ 2}{d 2} & [ Mathematical 2 ] \\ Q 3 = A 3 ( T 2 - T 3 ) \frac{λ3}{d 3} & [ Mathematical 3 ] \\ Q 4 = A 4 ( T 3 - T 4 ) \frac{λ 2}{d 2} & [ Mathematical 4 ]\end{matrix}$$

Note that λ1, λ2, and λ3 are thermal conductivity of the heat conductive material 6, the first resin film 52 (second resin film 53), and the metallic plate 51. d1, d2, and d3 are thicknesses of the heat conductive material 6, the first resin film 52 (second resin film 53), and the metallic plate 51. Tc, T1, T2, T3, and T4 are temperatures of the inner surface of the heat conductive material 6 (the outer surface of the electronic part 32), the inner surface of the first resin film 52 (the outer surface of the heat conductive material 6), the inner surface of the metallic plate 51 (the outer surface of the first resin film 52), the inner surface of the second resin film 53 (the outer surface of the metallic plate 51), and the outer surface of the second resin film 53. A1, A2, A3, and A4 are variables varying according, for example, to areas of the heat conductive material 6, the first resin film 52 (second resin film 53), and the metallic plate 51.

Considering the heat transport quantity Q4 through the second resin film 53 in the thickness direction, as the temperature difference T3−T4 of the second resin film 53 and the thermal conductivity λ2 of the second resin film 53 are greater, the heat transport quantity Q4 through the second resin film 53 in the thickness direction increases. In other words, heat dissipation performance of the metallic plate 51 is enhanced. On the other hand, as the thickness d2 of the second resin film 53 is greater, the heat transport quantity Q4 decreases. In other words, the heat dissipation performance of the metallic plate 51 is lowered.

In other words, in comparison with the case where the resin-coated metallic plate 50 and the metallic plate 51 are the same in thickness, the resin-coated metallic plate 50 includes the second resin film 53 lower in thermal conductivity (higher in thermal resistance) than the metallic plate 51 having a thickness of d, and the heat dissipation performance of the metallic plate 51 is lowered accordingly. In other words, the temperature of the metallic plate 51 is raised due to the thermal resistance of the second resin film 53. A heat dissipation performance lowering allowance of the metallic plate 51 depends on the thickness d, and, therefore, can be expressed as ΔTa(d).

On the other hand, the heat transport quantity Q based on heat radiation from the outer surface of the second resin film 53 at temperature T4 to the external environment at temperature T0 is expressed by the following mathematical formula 5.

Q=AεT4−T0) [Mathematical 5]

Note that ε is a thermal emissivity of the outer surface of the second resin film 53, and A is a variable varying according, for example, to areas of the second resin film 53.

As the temperature difference T4−T0 between the temperature T4 of the outer surface of the second resin film 53 and the external environmental temperature T0 and the thermal emissivity ε of the outer surface of the second resin film 53 are greater, the heat transport quantity Q based on thermal radiation is enhanced. Here, the thermal emissivity ε of the outer surface of the second resin film 53 depends on the thickness d of the second resin film 53. As the thickness of the second resin film 53 increases, the thermal emissivity ε of the outer surface of the second resin film 53 is enhanced, and, when the second resin film 53 reaches a predetermined thickness, the thermal emissivity ε of the outer surface of the second resin film 53 becomes constant. In other words, with the thickness d of the second resin film 53 set to be equal to or more than a predetermined value, the outer surface of the second resin film 53 has a high thermal emissivity ε, and the heat transport quantity Q based on thermal radiation increases.

In other words, the resin-coated metallic plate 50, as compared to the case with only the metallic plate 51, includes the second resin film 53 having a thickness d, and, accordingly, the thermal emissivity ε of the outer surface of the second resin film 53 increases, so that the heat dissipation performance of the metallic plate 51 is enhanced. In other words, the temperature of the metallic plate 51 is lowered due to the increase in the thermal emissivity ε of the outer surface of the second resin film 53. A heat dissipation performance enhancement allowance of the metallic plate 51 depends on the thickness d, and can be expressed as ΔTb(d).

FIG. 3 is a diagram schematically representing the relation between the heat dissipation performance lowering allowance ΔTa(d) of the metallic plate 51 based on heat conduction of the second resin film and the heat dissipation performance enhancement allowance ΔTb(d) of the metallic plate 51 based on thermal radiation.

The heat dissipation performance lowering allowance ΔTa (d) of the metallic plate 51 with the second resin film 53 is proportional to the thickness d. On the other hand, the heat dissipation performance enhancement allowance ΔTb(d) of the metallic plate 51 with the second resin film 53 is lowered due to enhancement of the thermal emissivity of the surface until the thickness d of the second resin film 53 becomes a predetermined thickness. When the thickness d of the second resin film 53 reaches a thickness of equal to or more than a predetermined value, the thermal emissivity of the outer surface of the second resin film 53 becomes a constant value, and, therefore, the heat dissipation performance enhancement allowance ΔTb(d) of the metallic plate 51 with the second resin film 53 also becomes constant.

The total heat dissipation performance enhancement allowance of the resin-coated metallic plate 50 in which the heat dissipation performance lowering allowance ΔTa(d) of the metallic plate 51 with the second resin film 53 is offset by the heat dissipation performance enhancement allowance ΔTb (d) of the metallic plate 51 with the second resin film 53 can be expressed as ΔTa (d)+ΔTb(d). In the case where a maximum thickness of the second resin film 53 such that ΔTa(d)+ΔTb (d)=0 is dmax, the heat dissipation performance of the metallic plate 51 is enhanced if 0<d<dmax is satisfied.

Note that the relation between the heat dissipation performance lowering allowance ΔTa(d) with the second resin film 53 and the heat dissipation performance enhancement allowance ΔTb(d) with the second resin film 53 is not limited to FIG. 3. The heat dissipation performance lowering allowance ΔTa(d) with the second resin film 53 is not necessarily linear, and the inclination of the graph differs from resin material to resin material. Further, the thickness d of the second resin film 53 at which the heat dissipation performance enhancement allowance ΔTb(d) with the second resin film 53 becomes constant, also, differs from resin material to resin material.

As has been described above, the maximum thickness dmax of the second resin film 53 and the thickness d of the second resin film 53 at which the total heat dissipation performance enhancement allowance ΔTa(d)+ΔTb(d) with the second resin film 53 reaches its maximum vary depending on the material of the second resin film 53 used. The thickness d of the second resin film 53 may preferably be set according to differences in the material of the second resin film 53, the material and thickness of the metallic plate 51, the heat generation quantity of the electronic part 3, and the thickness and thermal conductivity of the heat conductive material 6. For example, the thickness d of the second resin film 53 is set in the range of 0<d<300 μm. As a result, the degree of freedom in designing the second resin film 53 can be enhanced.

Note that the thickness of the second resin film 53 may be on the order of 80 μm. As the second resin film 53 is thinner, the heat dissipation performance lowering allowance ΔTa(d) based on heat conduction is suppressed. On the other hand, as the second resin film 53 is thinner, durability performance is lowered. The metallic plate 51 and the second resin film 53 are formed of different materials from each other, and differ in linear expansion coefficients. In other words, the metallic plate 51 and the second resin film 53 differ in deformation allowances at the time of a temperature variation; therefore, a stress is generated in the second resin film 53, and as the second resin film 53 is thinner, it is possible to crack or peel off, for example. Therefore, the second resin film 53 should have a certain extent of film thickness. Accordingly, from the viewpoint of durability and production, the film thickness is desirably, for example, approximately 80 μm.

More preferably, the thickness of the second resin film 53 may be on the order of 40 μm. The thermal emissivity of the outer surface of the second resin film 53 is enhanced as the thickness d of the second resin film 53 increases. For example, it is assumed that the thermal emissivity of the second resin film 53 becomes constant when the thickness is d′. The thickness d′ of the second resin film 53 differs from resin material to resin material. For example, in the case where the material of the second resin film 53 is PBT, the thickness d′ of the second resin film 53 is approximately 40 μm. With the thickness of a thin film resin material 52 on the order of 40 μm, a high thermal emissivity can be secured while restraining lowering in heat dissipation performance due to the thermal resistance of the second resin film 53. It is to be noted, however, that since problems from the viewpoint of durability and production are generated as the second resin film 53 is thinner as aforementioned, the thickness is desirably, for example, on the order of 40 μm.

According to this configuration, since the metallic plate 51 facing the electronic part 32 is provided at part of the housing 20 and the outer surface of the metallic plate 51 is covered with the second resin film 53 thinner than the metallic plate 51, the heat of the metallic plate 51 is efficiently dissipated to the exterior by thermal radiation of the second resin film 53. Therefore, a heat dissipation property for the electronic part 32 can be enhanced through the metallic plate 51 and the second resin film 53. Further, with the metallic plate 51 provided only at part of the housing 20, the electronic controller 11 can be lightened in weight, while enhancing the heat dissipation property for the electronic part 32.

Further, in the case where the temperature rise of the metallic plate 51 due to the thermal resistance of the second resin film 53 is ΔTa(d), in the case where the temperature fall of the metallic plate 51 due to the thermal radiation of the second resin film 53 is ΔTb(d), and in the case where the maximum thickness of the second resin film 53 such that ΔTa(d)+ΔTb(d)=0 is dmax, the thickness d of the second resin film 53 is set in the range of 0<d<dmax. By this, the degree of freedom in designing the thickness of the second resin film 53 can be enhanced.

Furthermore, since the housing 20 and the second resin film 53 covering the outer surface of the metallic plate 51 are formed from the same resin material, high adhesion can be secured between the housing 20 and the second resin film 53.

Further, the housing 20 is formed with the stepped part 21 capable of supporting the circuit board 30, and the electronic part 32 is mounted at a position spaced inward by a predetermined distance from a portion supported by the stepped part 21 of the circuit board 30. By this, the heat of the electronic part 32 can be dissipated to the housing 20 through the stepped part 21. Further, a peripheral edge of the circuit board 30 can enter the stepped part 21, so that the circuit board 30 large in width can be accommodated in the housing 20.

### Embodiment 2

Next, an electronic controller 12 according to Embodiment 2 will be described. Note that the electronic controller 12 according to Embodiment 2 differs from the electronic controller 11 according to Embodiment 1 only in the number of the electronic parts, the heat conductive materials, and the resin-coated metallic plates, and is similar to the electronic controller 11 according to Embodiment 1 in the other configurations. Therefore, the difference from Embodiment 1 will be described primarily.

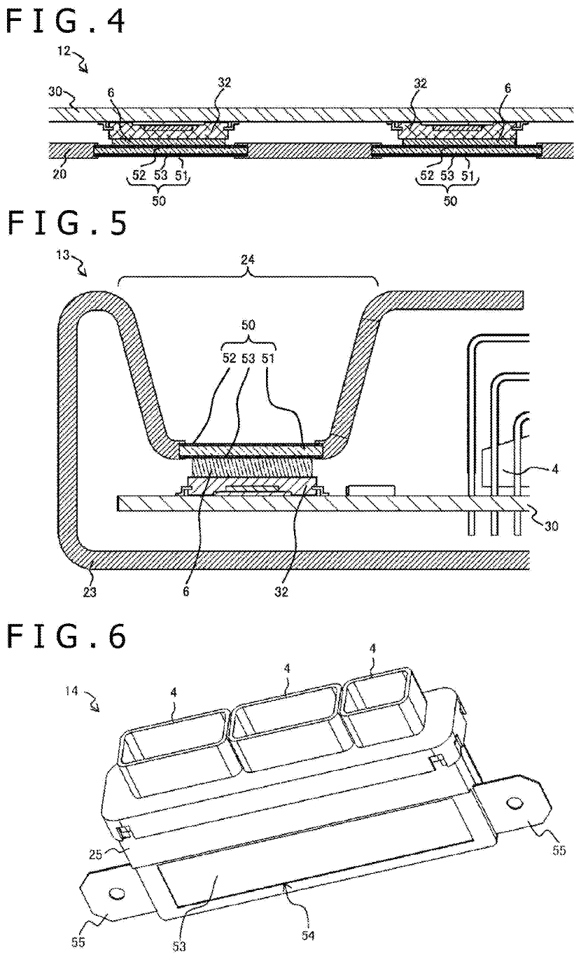

FIG. 4 is a sectional view of the electronic controller according to Embodiment 2.

A circuit board 30 of the electronic controller 12 has two electronic parts 32 mounted thereon, and heat conductive materials 6 and resin-coated metallic plates 50 which face the respective electronic parts 32 are provided at parts of a housing 20. Note that the housing 20 may be formed with projections and recesses according to the heights of the electronic parts 32.

### Embodiment 3

Next, an electronic controller 13 according to Embodiment 3 will be described. Note that the electronic controller 13 according to Embodiment 3 differs from the electronic controller 11 according to Embodiment 1 only in the configuration of the housing, and is similar to the electronic controller 11 according to Embodiment 1 in the other configurations. Therefore, the difference from Embodiment 1 will be described primarily.

FIG. 5 is a sectional view of the electronic controller according to Embodiment 3.

A housing 23 of the electronic controller 13 is formed with a recess 24 recessed toward an electronic part 32, and a resin-coated metallic plate 50 (metallic plate 51) facing the electronic part 32 is provided at the recess 24. Note that the recess 24 need only be recessed to such an extent as to narrow a clearance between the resin-coated metallic plate 50 and the electronic part 32. As a result, the resin-coated metallic plate 50 and the electronic part 32 are close to each other, the thermal emissivity of the resin-coated metallic plate 50 can be enhanced, and the heat of the electronic part 32 dissipated by thermal radiation can be efficiently absorbed by the resin-coated metallic plate 50. Further, in the case where a plurality of electronic parts 32 are mounted on a circuit board 30, recesses 24 facing the respective electronic parts 32 may be formed.

### Embodiment 4

Next, an electronic controller 14 according to Embodiment 4 will be described. Note that the electronic controller 14 according to Embodiment 4 differs from the electronic controller 11 according to Embodiment 1 only in the configurations of the housing and the metallic plate, and is similar to the electronic controller 11 according to Embodiment 1 in the other configurations. Therefore, the difference from Embodiment 1 will be described primarily.

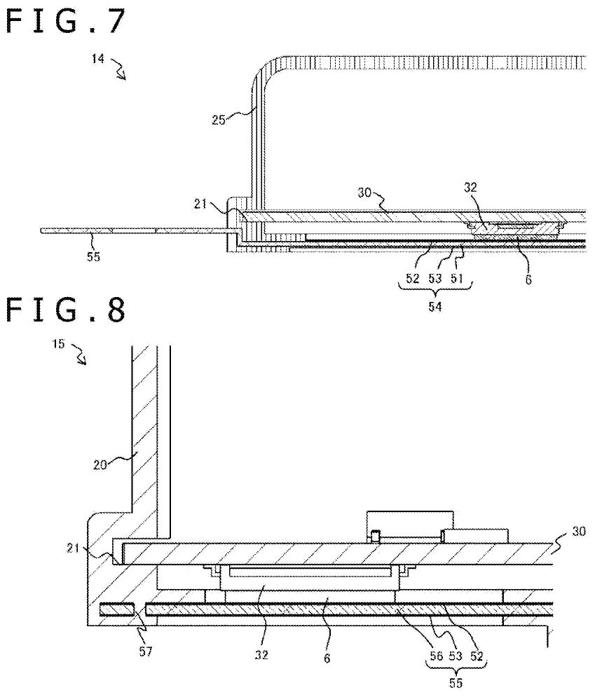

FIG. 6 is a perspective view of the electronic controller according to Embodiment 4, and FIG. 7 is a sectional view of the electronic controller according to Embodiment 4.

A housing 25 of the electronic controller 14 is formed with bracket sections 55 that are mounted to a vehicle body. The bracket sections 55 are formed on both side in regard of a longitudinal direction of the housing 25. The bracket sections 55 are end portions of a metallic plate 51 that project from the housing 25. A resin-coated metallic plate 54 (metallic plate 51) is provided on the bracket section 55 side of the housing 25, with a circuit board 30 interposed therebetween. The metallic plate 51 can be insert molded in relation to the housing 25, in a state in which parts thereof are bent into the shapes of the bracket sections 55. The bracket sections 55 may have various shapes according, for example, to the shape of the vehicle body.

The metallic plate 51 may not have a first resin film 52 and a first resin film 53 only at the bracket sections 55, that is, the metallic plate 51 may be exposed. In other words, at the time of insert molding the metallic plate 51 in relation to the housing 25, the first resin film 52 and the first resin film 53 may be provided, for enhancing the thermal emissivity, at those portions of the metallic plate 50 which constitute an outer wall of the housing 25. At the bracket sections 55 fixed in contact with the vehicle body side, of the resin-coated metallic plate 50, the metallic plate 51 may be exposed for the purpose of taking a GND with the vehicle fixation side.

### Embodiment 5

Next, an electronic controller 15 according to Embodiment 5 will be described. Note that the electronic controller 15 according to Embodiment 5 differs from the electronic controller 11 according to Embodiment 1 only in the configuration of the metallic plate, and is similar to the electronic controller 11 according to Embodiment 1 in the other configurations. Therefore, the difference from Embodiment 1 will be described primarily.

FIG. 8 is a sectional view of the electronic controller according to Embodiment 5.

A metallic plate 56 of the electronic controller 15 is formed with a plurality of through-holes 57 (in FIG. 7, only one through-hole 57 is depicted, and the other holes are omitted), and the through-holes 57 are filled with parts of a housing 20. Here, at the time of insert molding the metallic plate 56 in relation to the housing 20, parts of the resin material of the housing 20 flow into the through-holes 57. The through-holes 57 are partly or entirely filled with the resin material having flowed thereinto. As a result, mounting strength of the metallic plate 56 and the housing 20 can be enhanced.

### Embodiment 6

Next, an electronic controller 16 according to Embodiment 6 will be described. Note that the electronic controller 16 according to Embodiment 6 differs from the electronic controller 11 according to Embodiment 1 only in the configuration of the housing, and is similar to the electronic controller 11 according to Embodiment 1 in the other configurations. Therefore, the difference from Embodiment 1 will be described primarily.

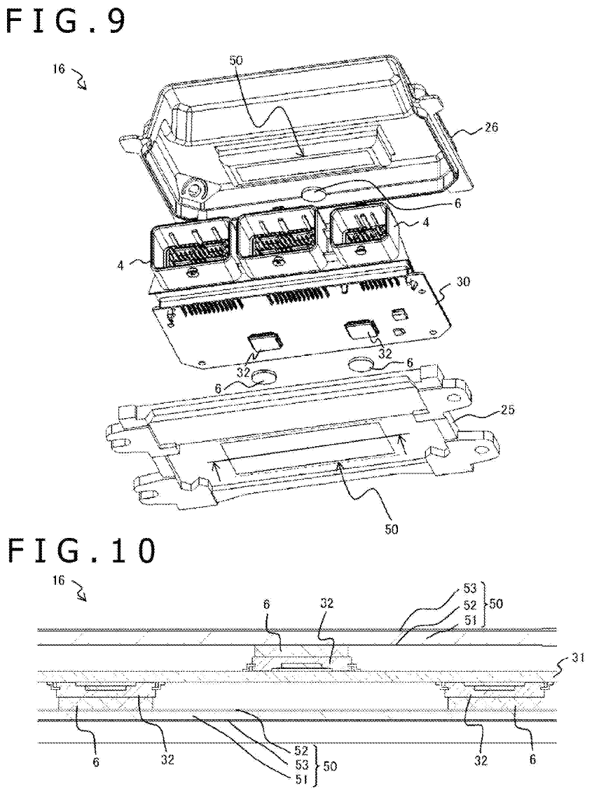

FIG. 9 is an exploded perspective view of the electronic controller according to Embodiment 6, and FIG. 10 is a sectional view of the electronic controller according to Embodiment 6.

A housing 16 of the electronic controller 16 includes a base 25 and a cover 26, and respective resin-coated metallic plates 50 (metallic plates 51) are provided on the base 25 and the cover 26. In other words, the housing 16 is provided with the metallic plate 51 on each side of a circuit board 30. Note that the resin-coated metallic plate 50 (metallic plate 51) may be provided on either one of the base 25 and the cover 26. After the circuit board 30 is mounted on the base 25, the cover 10 is joined to the base 25. A heat conductive material 6 is disposed on the base 25, before mounting the circuit board 30. As a result, the clearance between an electronic part 32 mounted on the circuit board 30 and the resin-coated metallic plate 50 provided on the base 25 is narrowed, and it is possible to enhance heat dissipation performance and to reduce cost through a reduction in the amount of the heat conductive material 6 used.

After the circuit board 30 is mounted on the base 25, the heat conductive material 6 is disposed on the circuit board 30 or the electronic part 32, and the cover 26 is mounted, whereby the heat generated from the electronic part 32 can be dissipated also to the cover 26 through the heat conductive material 6, and it is possible to further enhance heat dissipation performance.

### Embodiment 7

Next, an electronic controller 17 according to Embodiment 7 will be described. Note that the electronic controller 17 according to Embodiment 7 differs from the electronic controller 11 according to Embodiment 1 only in the configuration and layout of the circuit board, and is similar to the electronic controller 11 according to Embodiment 1 in the other configurations. Therefore, the difference from Embodiment 1 will be described primarily.

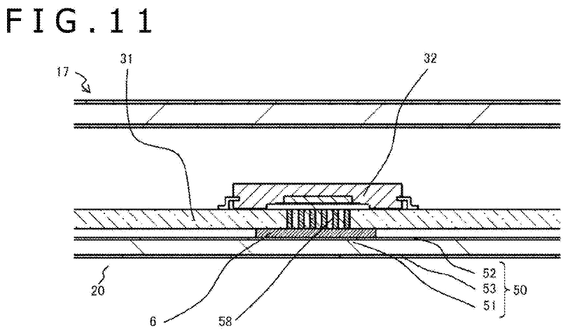

FIG. 11 is a sectional view of the electronic controller according to Embodiment 7.

An electronic part 32 is mounted on one surface of a circuit board 31 of the electronic controller 17, and that portion of the circuit board 31 at which the electronic part 32 is mounted is provided with a plurality of thermal vias 58. The heat generated from the electronic part 32 is transmitted to a resin-coated metallic plate 50 through the thermal vias 58 and a heat conductive material 6. The number and diameter of the thermal vias 58 may be considered variously according to the size and heat generation quantity of the electronic part 32, and the like. In addition, for example, a copper inlay in which a copper material is press fitted may be provided in place of the thermal vias 58, at that portion of the circuit board 31 at which the electronic part 32 is mounted.

According to this configuration, the resin-coated metallic plate 50 is provided on the opposite side of the circuit board 30 from the electronic part 32, whereby the clearance between the circuit board 30 and the resin-coated metallic plate 50 is narrowed, and, therefore, it is expected that the amount of a heat conductive material 6 used can be reduced, and the heat dissipated from the circuit board by thermal radiation can be efficiently absorbed by the resin-coated metallic plate 50.

Note that the present invention is not limited to the above-described embodiments, but includes various modifications. For example, the aforementioned embodiments have been described in detail for the purpose of easily understandably explaining the present invention, and the embodiment of the present invention is not necessarily limited to one that includes all the configurations described above. In addition, part of the configurations of an embodiment may be replaced by a configuration of another embodiment. Besides, to the configurations of an embodiment may be added configurations of another embodiment. In addition, with respect to part of the configurations of another embodiment, other configurations may be added, deleted, or replaced.

For example, in the above embodiments, the inner surface of the metallic plate 51 may be covered with the first resin film 52, exclusively of the exposed metal surface facing the electronic part 32, and the heat conductive material 6 may be provided between the electronic part 32 and the exposed metal surface. The metallic plate 51 may be insert molded in such a manner that at least its inner surface facing the electronic part 32 is exposed from the first resin film 52. As a result, the heat generated from the electronic part 3 can be transmitted to the heat conductive material 6, the heat can be transmitted directly from the heat conductive material 6 to the metallic plate 51, and the heat dissipation property for the electronic part 32 can be further enhanced.

For example, in the above embodiments, the heat conductive material 6 may not necessarily be provided between the electronic part 32 and the first resin film 52.

For example, in the above embodiments, the base, the cover, and the resin-coated metallic plate may have various shapes, and the number of the resin-coated metallic plates may be one or more.

### DESCRIPTION OF REFERENCE SYMBOLS

6: Heat conductive material, 11: Electronic controller, 12: Electronic controller, 13: Electronic controller, 14: Electronic controller, 15: Electronic controller, 16: Electronic controller, 17: Electronic controller, 20: Housing, 21: Stepped part, 24: Recess, 25: Base, 26: Cover, 30: Circuit board, 32: Electronic part, 50: Resin-coated metallic plate, 51: Metallic plate, 52: First resin film, 53: Second resin film, 54: Resin-coated metallic plate, 55: Bracket section, 56: Metallic plate, 57: Through-hole, 58: Thermal via

1. An electronic controller comprising:
a circuit board on which an electronic part is mounted; and
a housing accommodating the circuit board,
wherein a metallic plate facing the electronic part is provided at part of the housing, and
at least an outer surface of the metallic plate is covered with a resin film thinner than the metallic plate.

2. The electronic controller according to claim 1,
wherein in a case where a temperature rise of the metallic plate due to thermal resistance of the resin film is ΔTa(d), in a case where a temperature fall of the metallic plate due to thermal radiation of the resin film is ΔTb(d), and in a case where a maximum thickness of the resin film such that ΔTa(d)+ΔTb(d)=0 is dmax, a thickness d of the resin film is in a range of 0<d<dmax.

3. The electronic controller according to claim 2,
wherein the thickness d of the resin film is in a range of 0<d<300 μm.

4. The electronic controller according to claim 3,
wherein both surfaces of the metallic plate are covered with the resin film.

5. The electronic controller according to claim 1,
wherein an inner surface of the metallic plate is covered with the resin film, exclusively of an exposed metal surface facing the electronic part, and
a heat conductive material is provided between the electronic part and the exposed metal surface.

6. The electronic controller according to claim 1,
wherein the housing is formed with a recess recessed toward the electronic part, and
the metallic plate facing the electronic part is provided at the recess.

7. The electronic controller according to claim 1,
wherein the housing and the resin film are formed from a same resin material.

8. The electronic controller according to claim 7,
wherein, of the metallic plate, at least an inner surface facing the electronic part is insert molded in relation to the housing such as to be exposed from the resin film.

9. The electronic controller according to claim 8,
wherein the metallic plate is formed with a plurality of through-holes, and
the through-holes are filled with parts of the housing.

10. The electronic controller according to claim 1,
wherein the housing is formed with a bracket section attached to a vehicle body, and
the metallic plate is provided on the bracket section side of the housing, with the circuit board interposed therebetween.

11. The electronic controller according to claim 10,
wherein the bracket section is an end portion of the metallic plate that projects from the housing.

12. The electronic controller according to claim 1,
wherein the housing is provided with the metallic plate on each side of the circuit board.

13. The electronic controller according to claim 12,
wherein the housing includes a base and a cover covering the base, and
the metallic plate is provided on each of the base and the cover.

14. The electronic controller according to claim 13,
wherein the electric parts are mounted on both surfaces of the circuit board, and
a heat conductive material is provided between the electric part and the metallic plate.

15. The electronic controller according to claim 1,
wherein the housing is formed with a stepped part capable of supporting the circuit board, and
the electronic part is mounted at a position spaced inward by a predetermined distance from a portion of the circuit board which is supported by the stepped part.

16. The electronic controller according to claim 1,
wherein the circuit board is provided with a thermal via at a part where the electronic part is mounted, and
the metallic plate is provided on an opposite side of the circuit board from the electronic part and in such a manner as to face the thermal via.

17. The electronic controller according to claim 1,
wherein a metallic member is press fitted in a part of the circuit board where the electronic part is mounted, and
the metallic plate is provided on an opposite side of the circuit board from the electronic part and in such a manner as to face the metallic member.
